(19) United States
(12) Patent Application Publication
(10) Pub. No.: US 2026/0063960 A1
(43) Pub. Date: Mar. 5, 2026

(54) DISPLAY DEVICE

(71) Applicant: E Ink Holdings Inc., HSINCHU (TW)

(72) Inventors: Chen-Yun MA, HSINCHU (TW); Sheng-Long LIN, HSINCHU (TW)

(21) Appl. No.: 19/173,826

(22) Filed: Apr. 9, 2025

(30) Foreign Application Priority Data
Aug. 28, 2024 (TW) 113132451

(51) Int. Cl. G02F 1/167; G06F 3/14; H05K 1/18

(52) U.S. Cl. CPC G02F 1/167; G06F 3/1446; H05K 1/189; H05K 2201/10128

(57) ABSTRACT

A display device includes a tiling unit, a front light module disposed on the tiling unit, and a cover plate disposed on the front light module. The tiling unit includes a backplane and display panels. The display panels are disposed on the backplane in a first direction and have an angle greater than 0 degree and less than a predetermined angle with the backplane apiece. Each display panel has a terminal connection side and a counter side opposite to the terminal connection side. Among two adjacent display panels, the counter side of one of the two adjacent display panels is arranged corresponding to the terminal connection side of the other one of the two adjacent display panels, and the one of the two adjacent display panels covers the terminal connection side of the other one of the two adjacent display panels.

### CROSS-REFERENCE TO RELATED APPLICATION

This application claims priority to Taiwan Application Serial Number 113132451, filed Aug. 28, 2024, which is herein incorporated by reference in its entirety.

### BACKGROUND

### Field of Invention

The present disclosure relates to a display device. More particularly, the present disclosure relates to a display device including a tiling unit.

### Description of Related Art

With the development of the technology industry, display devices have been widely used in daily life. By tiling multiple display panels on the backplane, a large display device can be formed and used in large-scale display activities, such as advertising billboards. However, since the display panel has a board that cannot display the image, if the two adjacent display panels are tiled in a general flat manner, there will be an obvious interval between the two adjacent display panels resulting in the dark line at the tiling joint, which in turn affects the display quality.

### SUMMARY

At least one embodiment of the present disclosure provides a display device that can avoid the dark line at the tiling joint caused by the obvious interval between the two adjacent display panels, thereby improving the display quality of the display device.

The display device according to at least one embodiment of the present disclosure includes one or multiple tiling units, a front light module, a connecting material, and a cover plate. The tiling unit or each of the tiling units includes a backplane and multiple display panels. The display panels are disposed on the backplane in a first direction and have an angle greater than 0 degree and less than a predetermined angle with the backplane apiece. Each of the display panels has a terminal connection side and a counter side opposite to the terminal connection side, among adjacent two of the display panels, the counter side of one of the adjacent two of the display panels is arranged corresponding to the terminal connection side of the other one of the adjacent two of the display panels, and the one of the adjacent two of the display panels covers the terminal connection side of the other one of the adjacent two of the display panels. The front light module is disposed on the tiling unit or the tiling units. The connecting material is disposed between the tiling unit or the tiling units and the front light module. The cover plate is disposed on the front light module.

The display device according to at least another embodiment of the present disclosure includes one or multiple tiling units, a front light module, a connecting material, and a cover plate. The tiling unit or each of the tiling units includes a backplane, multiple display panels, and multiple supporting members. Each of the display panels has a terminal connection side and a counter side opposite to the terminal connection side, among adjacent two of the display panels, the counter side of one of the adjacent two of the display panels is arranged corresponding to the terminal connection side of the other one of the adjacent two of the display panels, and the one of the adjacent two of the display panels covers the terminal connection side of the other one of the adjacent two of the display panels. The supporting members are disposed between the display panels and the backplane, respectively. Each of the supporting members has an upper surface facing the display panels, and the backplane has a lower surface facing away from the display panels, where a distance between the upper surface and the lower surface gradually increases in the first direction. The front light module is disposed on the tiling unit or the tiling units. The connecting material is disposed between the tiling unit or the tiling units and the front light module. The cover plate is disposed on the front light module.

It is to be understood that both the foregoing general description and the following detailed description are by examples, and are intended to provide further explanation of the present disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic top view of a display device according to at least one embodiment of the present disclosure.

FIG. 2A is a schematic cross-sectional view taken along line A-A′ of FIG. 1.

FIG. 2B is a schematic cross-sectional view of a display device according to at least another embodiment of the present disclosure.

FIG. 3A to FIG. 3C are schematic top views of tiling units according to at least one embodiment of the present disclosure.

FIG. 4 is a schematic cross-sectional view of a display panel according to at least one embodiment of the present disclosure.

### DETAILED DESCRIPTION

The embodiments of the present disclosure are discussed in detail below. It will be appreciated, however, that the embodiments provide many applicable concepts which may be implemented in a wide variety of specific contexts. The discussed and disclosed embodiments are for illustrative purposes only and are not intended to limit the scope of patent applications in this case.

In the following description, in order to clearly present the technical features of the present disclosure, the dimensions of elements in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

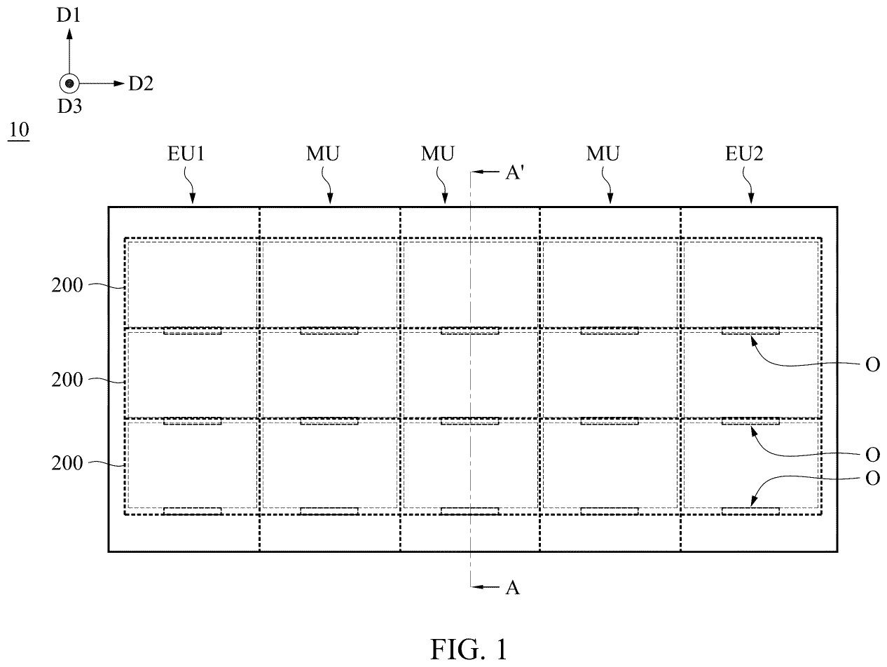

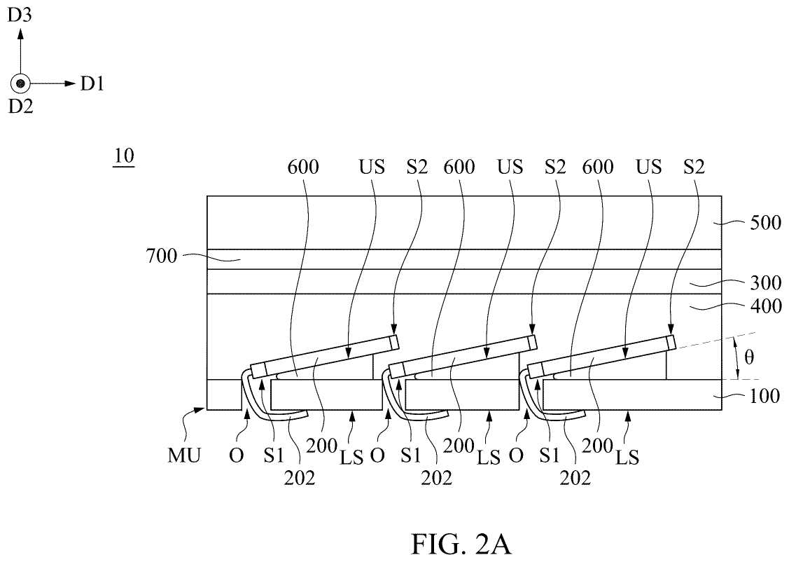

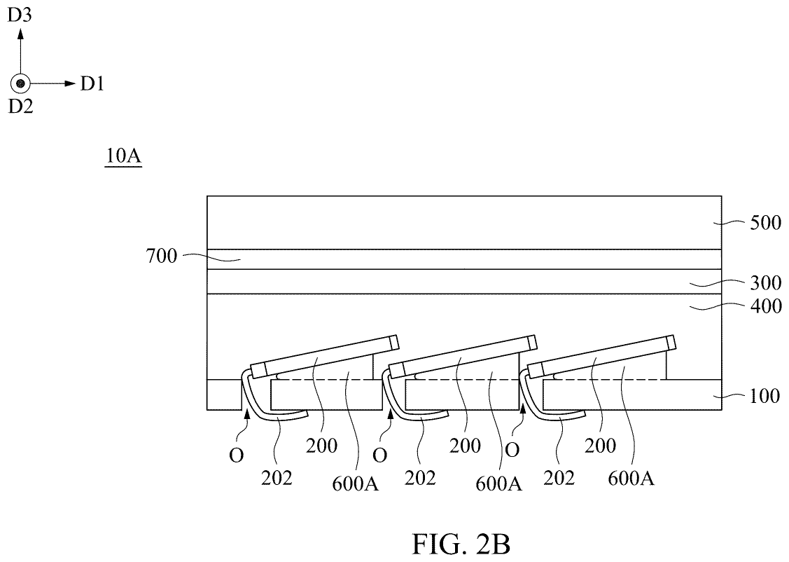

FIG. 1 is a schematic top view of a display device 10 according to at least one embodiment of the present disclosure. FIG. 2A is a schematic cross-sectional view taken along line A-A′ of FIG. 1. Referring to FIG. 1 and FIG. 2A, the display device 10 includes multiple tiling units EU1, MU, EU2, a front light module 300, a connecting material 400, and a cover plate 500. The front light module 300 is disposed on the tiling units EU1, MU, EU2, the connecting material 400 is disposed between the tiling units EU1, MU, EU2 and the front light module 300, and the cover plate 500 is disposed on the front light module 300. It should be understood that FIG. 1 merely illustrates five tiling units, but the present disclosure is not limited thereto. In other embodiments, the number of tiling units can be increased or decreased according to the size of the display device, that is, the display device can include one or multiple tiling units.

Each of the tiling units EU1, MU, EU2 (taking the tiling unit MU in FIG. 2A as an example) includes a backplane 100 and multiple display panels 200. The display panels 200 are disposed on the backplane 100 in a first direction D1, and have an angle θ greater than 0 degree and less than a predetermined angle with the backplane 100, respectively. In some embodiments, the predetermined angle may be 10 degrees, but the present disclosure is not limited thereto. In other embodiments, the predetermined angle may be 5 degrees. In other embodiments, the predetermined angle may be 1 degree.

Each of the display panels 200 has a terminal connection side S1 and a counter side S2 opposite to the terminal connection side S1. Among two adjacent display panels 200, the counter side S2 of one of the two adjacent display panels 200 is arranged corresponding to the terminal connection side S1 of the other one of the two adjacent display panels 200, and the one of the two adjacent display panels 200 covers the terminal connection side S1 of the other one of the two adjacent display panels 200. It should be understood that FIG. 2A merely illustrates three display panels, but the present disclosure is not limited thereto. In other embodiments, the number of display panels can be increased or decreased according to the size of the tiling unit.

Since the counter side S2 of one of the two adjacent display panels 200 is arranged corresponding to the terminal connection side S1 of the other one of the two adjacent display panels 200, and the one of the two adjacent display panels 200 covers the terminal connection side S1 of the other one of the two adjacent display panels 200, the dark line at the tiling joint caused by the obvious interval between the two adjacent display panels 200 can be avoided, thereby improving the display quality of the display device 10. Furthermore, through the tiling method of inclined stacking with an angle θ greater than 0 degree and less than the predetermined angle between the display panels 200 and the backplane 100, the difference in the distance from each of the display panels 200 to the front light module 300 will not be too large, and thus the overall thickness of the display device 10 will not be too thick. When the angle θ between the display panel 200 and the backplane 100 is in a range greater than 0 degree and less than the predetermined angle, the visual effect is less likely to be affected. That is, the smaller the angle θ between the display panel 200 and the backplane 100 is, the less it will affect the visual effect.

Referring to FIG. 1 and FIG. 2A, the backplane 100 has multiple openings O, and each of the display panels 200 includes a flexible circuit board 202 disposed at the terminal connection side S1. The flexible circuit boards 202 are respectively inserted into the openings O and extend under the backplane 100. It should be understood that FIG. 1 and FIG. 2A merely illustrate three openings, but the present disclosure is not limited thereto. In other embodiments, the number of openings can be increased or decreased according to the number of display panels in the tiling unit, which may or may not be the same as the number of display panels.

As shown in FIG. 1, the tiling units EU1, MU, EU2 are tiled and arranged in a second direction D2 that is not substantially parallel to the first direction D1. For example, the second direction D2 may be substantially perpendicular to the first direction D1. In some embodiments, the extending direction of the opening O is substantially parallel to the terminal connection side S1 of the display panel 200, and may also be substantially parallel to the short side of the backplane 100. That is, the extending direction of the opening O may be substantially parallel to the second direction D2, i.e., substantially perpendicular to the first direction D1.

As shown in FIG. 2A, each of the tiling units EU1, MU, EU2 (taking the tiling unit MU in FIG. 2A as an example) further includes multiple supporting members 600 disposed between the display panels 200 and the backplane 100, respectively. It should be understood that FIG. 2A merely illustrates three supporting members, but the present disclosure is not limited thereto. In other embodiments, the number of supporting members can be increased or decreased according to the number of display panels in the tiling unit.

The supporting member 600 has an upper surface US facing the display panel 200, the backplane 100 has a lower surface LS facing away from the display panel 200, and the distance between the upper surface US of the supporting member 600 and the lower surface LS of the backplane 100 gradually increases in the first direction D1. In detail, the distance between the upper surface US of the supporting member 600 and the lower surface LS of the backplane 100 in a third direction D3 gradually increases in the first direction D1, and the third direction D3 is substantially perpendicular to the first direction D1 and the second direction D2. Therefore, disposing the display panel 200 on the supporting member 600 can make the angle θ between the display panel 200 and the backplane 100 greater than 0 degrees and less than the predetermined angle. Between two adjacent display panels 200, in the normal line of the backplane 100 (i.e., the third direction D3), the counter side S2 of one of the two adjacent display panels 200 overlaps the terminal connection side S1 of the other one of the two adjacent display panels 200.

Through the tiling method of inclined stacking of the display panels 200 on the backplane 100, the dark line at the tiling joint caused by the obvious interval between the two adjacent display panels 200 can be avoided, thereby improving the display quality of the display device 10. Furthermore, the difference in the distance from each of the display panels 200 to the front light module 300 will not be too large, and thus the overall thickness of the display device 10 will not be too thick. When the angle θ between the display panel 200 and the backplane 100 is in a range greater than 0 degree and less than the predetermined angle, the visual effect is less likely to be affected.

Referring to FIG. 2A, the display device 10 further includes a connecting layer 700 disposed between the front light module 300 and the cover plate 500. In detail, the connecting layer 700 connects to the front light module 300 and the cover plate 500, and the connecting material 400 is filled between the front light module 300 and the backplane 100, and covers and surrounds the display panels 200.

In addition, in the display device 10, one front light module 300 and one cover plate 500 cover multiple display panels 200 or even multiple tiling units EU1, EU2, MU in the normal line of the backplane 100 (i.e., the third direction D3). That is, the size of the front light module 300 and the size of the cover plate 500 are respectively larger than the size of the display panel 200, or even larger than the size of the tiling unit EU1, EU2, or MU. By the aforementioned design, the front light module 300 and the cover plate 500 can be formed directly according to the size of the display device 10 without the need for tiling, which reduces the optical issue caused by multi-layer tiling and further improves the display quality of the display device 10.

In some embodiments, the backplane 100 may be a transparent substrate or an opaque substrate, and the front light module 300 may include a light bar (not shown) and a light guide plate (not shown). The cover plate 500 may be a transparent substrate, such as a glass plate or a transparent plastic plate, and the material of the transparent plastic plate may be polyethylene terephthalate (PET), poly (methyl methacrylate) (PMMA), polycarbonate (PC), cyclic olefin copolymer (COC), cyclic olefin polymer (COP) and/or other suitable materials. The connecting material 400 may be optical clear resin (OCR) and/or other suitable materials. By using the optical clear resin as the connecting material 400, the difference in distance between each of the display panels 200 and the front light module 300 can be filled in, so that the connecting surface between the connecting material 400 and the front light module 300 is approximately flat. The material of the supporting members 600 may include bakelite, glass fiber, plastic, foam, silicon, rubber, optical clear adhesive (OCA) or optical clear resin. The connecting layer 700 may be optical clear adhesive, optical clear resin, and/or other suitable materials.

FIG. 2B is a schematic cross-sectional view of a display device 10A according to at least another embodiment of the present disclosure. Referring to FIG. 2B, the structures, the materials, and the relative positions of most elements in the display device 10A of FIG. 2B and the display device 10 of FIG. 2A are the same, and the schematic top view of the display device 10A of FIG. 2B is substantially the same as the schematic top view of the display device 10 of FIG. 2A, so the same features are not repeated here. The difference between the two embodiments is that the material of the supporting members 600A of the display device 10A is the same as the material of the backplane 100. In some embodiments, the supporting members 600A and the backplane 100 may be formed in the same process, that is, the supporting members 600A and the backplane 100 are integrally formed.

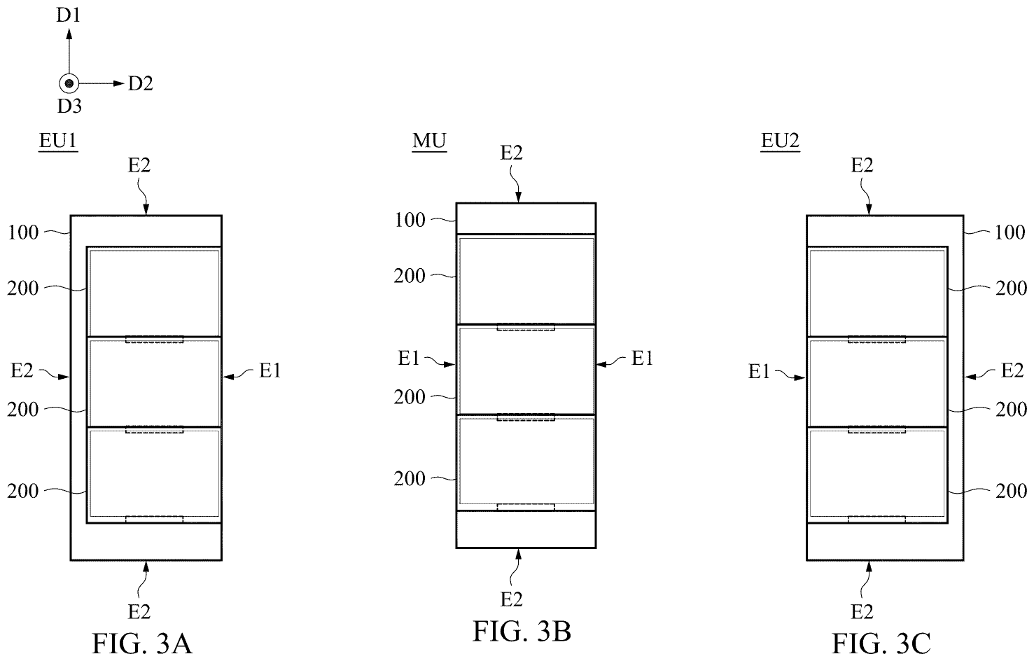

FIG. 3A to FIG. 3C are schematic top views of the tiling units EU1, MU, EU2 of the display device 10, 10A. Referring to FIG. 1 and FIG. 3A to FIG. 3C. The tiling units EU1, MU, EU2 have a tiling edge E1 that is tiled with the adjacent tiling unit and an exposed edge E2 that is not tiled with the adjacent tiling unit. At the tiling edge E1, the backplane 100 of the tiling unit EU1, MU, or EU2 does not protrude from the display panels 200. At the exposed edge E2, the backplane 100 of the tiling unit EU1, MU, or EU2 protrudes from the display panels 200. By the aforementioned design, the dark line at the tiling joint caused by the protruding portion of the backplane 100 between adjacent tiling units can be avoided, thereby improving the display quality of the display device 10, 10A.

In some embodiments, the backplane 100 may be flush with the display panels 200 at the tiling edge E1. In other embodiments, the display panel s 200 may protrude from the backplane 100 at the tiling edge E1. In addition, the backplane 100 may not protrude from the display panels 200 at the exposed edge E2, that is, the backplane 100 may be flush with the display panels 200 at the exposed edge E2, or the display panels 200 may protrude from the backplane 100 at the exposed edge E2.

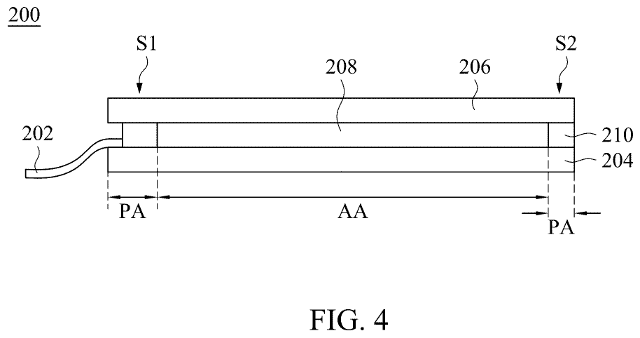

FIG. 4 is a schematic cross-sectional view of the display panel 200 of the display device 10, 10A. Referring to FIG. 4, the display panel 200 includes a substrate 204, a protective layer 206 and an electronic ink layer 208. The electronic ink layer 208 is disposed between the substrate 204 and the protective layer 206. In addition, the display panel 200 has a display area AA and a peripheral area PA, and further includes a sealant 210 disposed between the substrate 204 and the protective layer 206, surrounding the electronic ink layer 208, and located in the peripheral area PA.

The substrate 204 may be an array substrate, which may include, for example, pixel electrodes (not shown) and switching elements (not shown, such as transistors) or other electronic components (not shown, such as capacitors). As shown in FIG. 4, the flexible circuit board 202 is electrically connected to the substrate 204 at the terminal connection side S1 to drive the pixel electrodes and switching elements or other electronic components. Therefore, the width of the peripheral area PA at the terminal connection side S1 is larger than the width of the peripheral area PA at the counter side S2.

Therefore, in two adjacent display panels 200, by disposing the counter side S2 with a smaller width of the peripheral area PA of one of the two adjacent display panels 200 on the terminal connection side S1 with a larger width of the peripheral area PA of the other one of the two adjacent display panels 200, the dark line caused by exposing the peripheral area PA of the terminal connection side S1 with a larger width at the tiling joint can be avoided, thereby improving the display quality of the display device 10, 10A.

In some embodiments, the material of the protective layer 206 may be polyimide (PI), polyethylene terephthalate (PET), poly (methyl methacrylate) (PMMA), polycarbonate (PC), cyclic olefin copolymer (COC), cyclic olefin polymer (COP) and/or other suitable materials. The electronic ink layer 208 may be an electrophoretic layer, an electrowetting layer, or an electronic liquid powder layer.

In summary, in at least one embodiment of the display device of the present disclosure, the counter side of one of the two adjacent display panels is arranged corresponding to the terminal connection side of the other one of the two adjacent display panels, and the one of the two adjacent display panels covers the terminal connection side of the other one of the two adjacent display panels, the dark line at the tiling joint caused by the obvious interval between the two adjacent display panels can be avoided, thereby improving the display quality of the display device. Furthermore, through the tiling method of inclined stacking with an angle greater than 0 degree and less than the predetermined angle between the display panels and the backplane, the difference in the distance from each of the display panels to the front light module will not be too large, and thus the overall thickness of the display device will not be too thick. When the angle between the display panel and the backplane is in a range greater than 0 degree and less than the predetermined angle, the visual effect is less likely to be affected.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A display device, comprising:
one or a plurality of tiling units, wherein the tiling unit or each of the tiling units comprises:
a backplane; and
a plurality of display panels, disposed on the backplane in a first direction and have an angle greater than 0 degree and less than a predetermined angle with the backplane apiece, wherein each of the display panels has a terminal connection side and a counter side opposite to the terminal connection side, among adjacent two of the display panels, the counter side of one of the adjacent two of the display panels is arranged corresponding to the terminal connection side of the other one of the adjacent two of the display panels, and the one of the adjacent two of the display panels covers the terminal connection side of the other one of the adjacent two of the display panels;
a front light module, disposed on the tiling unit or the tiling units;
a connecting material, disposed between the tiling unit or the tiling units and the front light module; and
a cover plate, disposed on the front light module.

2. The display device of claim 1, wherein the backplane has a plurality of openings, and each of the display panels comprises a flexible circuit board disposing at the terminal connection side, wherein the flexible circuit boards are respectively inserted into the openings and extend underneath the backplane.

3. The display device of claim 2, wherein an extending direction of the opening is parallel to the terminal connection side.

4. The display device of claim 1, wherein the tiling unit or each of the tiling units further comprises:
a plurality of supporting members, disposed between the display panels and the backplane, respectively.

5. The display device of claim 4, wherein each of the supporting members has an upper surface facing the display panels, and the backplane has a lower surface facing away from the display panels, wherein a distance between the upper surface and the lower surface gradually increases in the first direction.

6. The display device of claim 4, wherein a material of the supporting members comprises bakelite, glass fiber, plastic, foam, silicon, rubber, optical clear adhesive or optical clear resin.

7. The display device of claim 4, wherein a material of the supporting members is the same as a material of the backplane.

8. The display device of claim 1, wherein each of the display panels comprises:
a substrate;
a protective layer; and
an electronic ink layer, disposed between the substrate and the protective layer.

9. The display device of claim 1, wherein the tiling units are tiled in a second direction not parallel to the first direction, and each of the tiling units has a tiling edge tiled with adjacent one of the tiling units, wherein at the tiling edge, the backplane of the tiling unit does not protrude from the display panels.

10. The display device of claim 9, wherein each of the tiling units has an exposed edge not tiled with the adjacent one of the tiling units, wherein at the exposed edge, the backplane of the tiling unit protrudes from the display panels.

11. The display device of claim 1, wherein the predetermined angle is within 5 to 10 degrees.

12. The display device of claim 1, wherein the front light module covers the display panels in a normal line of the backplane.

13. The display device of claim 1, wherein the cover plate covers the display panels in a normal line of the backplane.

14. A display device, comprising:
one or a plurality of tiling units, wherein the tiling unit or each of the tiling units comprises:
a backplane;
a plurality of display panels, disposed on the backplane in a first direction, wherein each of the display panels has a terminal connection side and a counter side opposite to the terminal connection side, among adjacent two of the display panels, the counter side of one of the adjacent two of the display panels is arranged corresponding to the terminal connection side of the other one of the adjacent two of the display panels, and the one of the adjacent two of the display panels covers the terminal connection side of the other one of the adjacent two of the display panels; and
a plurality of supporting members, disposed between the display panels and the backplane, respectively, wherein each of the supporting members has an upper surface facing the display panels, and the backplane has a lower surface facing away from the display panels, wherein a distance between the upper surface and the lower surface gradually increases in the first direction;
a front light module, disposed on the tiling unit or the tiling units;
a connecting material, disposed between the tiling unit or the tiling units and the front light module; and
a cover plate, disposed on the front light module.

15. The display device of claim 14, wherein a material of the supporting members comprises bakelite, glass fiber, plastic, foam, silicon, rubber, optical clear adhesive or optical clear resin.

16. The display device of claim 14, wherein a material of the supporting members is the same as a material of the backplane.

17. The display device of claim 14, wherein each of the display panels comprises:
a substrate;
a protective layer; and
an electrophoretic layer, disposed between the substrate and the protective layer.

18. The display device of claim 14, wherein the tiling units are tiled in a second direction not parallel to the first direction, and each of the tiling units has a tiling edge tiled with adjacent one of the tiling units, wherein at the tiling edge, the backplane of the tiling unit does not protrude from the display panels.

19. The display device of claim 18, wherein each of the tiling units has an exposed edge not tiled with the adjacent one of the tiling units, wherein at the exposed edge, the backplane of the tiling unit protrudes from the display panels.
